(19) United States
(12) Patent Application Publication
(10) Pub. No.: US 2010/0323509 A1
(43) Pub. Date: Dec. 23, 2010

(54) Nonvolatile semiconductor memory device and method of manufacturing the same

(76) Inventors: Sang-min Shin, Yongin-si (KR); Kwang-soo Seol, Yongin-si (KR); Young-gu Jin, Yongin-si (KR)

Correspondence Address: HARNESS, DICKEY & PIERCE, P.L.C., P.O. BOX 8910, RESTON, VA, 20195, US

(21) Appl. No.: 12/805,823

(22) Filed: Aug. 20, 2010

Related U.S. Application Data
(62) Division of application No. 11/723,081, filed on Mar. 16, 2007.

(30) Foreign Application Priority Data
Jul. 27, 2006 (KR) 10-2006-0070886

(51) Int. Cl. H01L 21/283

(52) U.S. Cl. 438/591; 257/E21.18

(57) ABSTRACT

Provided is a nonvolatile semiconductor memory device and a method of manufacturing the same. The nonvolatile semiconductor memory device may include a tunnel insulating layer formed on a semiconductor substrate, a charge trap layer including a dielectric layer doped with a transition metal formed on the tunnel insulating layer, a blocking insulating layer formed on the charge trap layer, and a gate electrode formed on the blocking insulating layer. The dielectric layer may be a high-k dielectric layer, for example, a HfO₂ layer. Thus, the data retention characteristics of the nonvolatile semiconductor memory device may be improved because a deeper charge trap may be formed by doping the high-k dielectric layer with a transition metal.

### PRIORITY STATEMENT

This U.S. nonprovisional application is a divisional of U.S. application Ser. No. 11/723,081, filed Mar. 16, 2007 and claims priority under 35 USC §121 to Korean Patent Application No. 2006-0070886, filed on Jul. 27, 2006, in the Korean Intellectual Property Office (KIPO), the entire contents of which are herein incorporated by reference.

### BACKGROUND

1. Field

Example embodiments relate to a nonvolatile semiconductor memory device with improved data retention characteristics and method of manufacturing the same.

2. Description of the Related Art

Nonvolatile semiconductor memory devices capable of storing data, erasing data electrically, and retaining stored data when power is removed have been a source of much interest.

The characteristics of a memory cell of a nonvolatile semiconductor memory device may vary according to the field in which the nonvolatile semiconductor memory device is used. For example, the gate stack of a transistor of the memory cell of a higher capacity nonvolatile semiconductor memory device, for example, a NAND (e.g., “not and”) type flash memory device, generally may have a structure in which a floating gate storing charges (e.g., storing data) and a control gate controlling the floating gate are sequentially stacked.

Because a conventional flash semiconductor memory device may use a conductive material, for example, polysilicon doped with a floating gate material, parasitic capacitance may increase between neighboring gate stacks when the device is highly integrated.

A nonvolatile semiconductor memory device known as a metal-oxide-insulator-oxide-semiconductor (MOIOS) (e.g., a silicon-oxide-nitride-oxide-semiconductor (SONOS) or a metal-oxide-nitride-oxide-semiconductor (MONOS)) has been researched as a solution of the aforementioned problems of flash semiconductor memory devices. A SONOS may use silicon as a control gate material and a MONOS may use metal as a control gate material.

A MOIOS memory device may use a charge trap layer, for example, silicon nitride (Si₃N₄), instead of a floating gate as a charge storing device. The MOIOS memory device may have an ONO structure, in which nitride and oxide may be sequentially stacked, instead of a stack structure formed of a floating gate and insulating layers stacked on the upper and lower portions between the substrate and the control gate as in the memory cell of a flash semiconductor memory device. The MOIOS memory device may use the shifting characteristic of the threshold voltage as charges may be trapped in the nitride layer.

FIG. 1 illustrates a cross-sectional view of a basic structure of a SONOS memory device (hereinafter referred to as a conventional SONOS device).

Referring to FIG. 1, the conventional SONOS device may include source and drain regions S and D separately formed in a semiconductor substrate 10 and a first silicon oxide (SiO₂) layer 12 formed on the semiconductor substrate 10 with both ends contacting the source and drain regions S and D. The first silicon oxide layer 12 may be for charge tunneling. A silicon nitride (Si₃N₄) layer 14 may be formed on the first silicon oxide layer 12. The silicon nitride layer 14, a material layer storing data, and charges that have tunneled through the first silicon oxide layer 12 may be trapped in the silicon nitride layer 14. A second silicon oxide layer 16 may be formed on the silicon nitride layer 14 as a blocking insulating layer to reduce or prevent the occurrence of charges passing through the silicon nitride layer 14 and moving upward. A gate electrode 18 may be formed on the second silicon oxide layer 16.

The dielectric constant of the silicon nitride layer 14, the first silicon oxide layer 12, and the second silicon oxide layer 16 of a MOIOS device (e.g., the conventional SONOS device illustrated in FIG. 1) may be lower. Further, the charge trap site density inside the silicon nitride layer 14 may not be sufficient, the operating voltage may be higher, the data recording (programming) speed and the erasing speed may be lower, and the retention time of the stored data may be shorter.

Current research has shown that when an aluminum oxide (Al₂O₃) layer is used as the blocking insulating layer instead of a silicon oxide layer in a SONOS type flash memory, the programming speed and the retention characteristics of the device may be improved. However, although the blocking insulating layer formed of aluminum oxide may suppress charges moving from the silicon nitride layer to an extent, the charge trap site density inside the silicon nitride layer may still not be sufficient. As such, the retention characteristics may not be improved by the aluminum oxide.

The silicon nitride layer used as a charge trap layer in the conventional SONOS device may be amorphous and the charge trap formed inside the silicon nitride layer may be of a non-stoichiometric composition. Thus, the distance between a valence band and a conduction band may be shorter and the energy band of the charge trap may have a broader distribution between the valence band and the conduction band. Accordingly, an upper or lower end of the energy band of the charge trap may be adjacent to the valence band or the conduction band. Because the dielectric constant of the silicon nitride layer may be lower (e.g., about 7 to 7.8), the density of the charge trap site that may be formed inside the conventional SONOS device may be lower.

For these reasons, no sufficient charge trap site may be formed inside the conventional silicon nitride layer and the upper or lower end of the energy band of the formed charge trap may be adjacent to the valence band or the conduction band. As such, charges trapped by the charge trap may likely be excited by thermal excitation. Thus, it may be difficult to obtain sufficient retention time using a conventional silicon nitride layer.

### SUMMARY

Example embodiments provide a nonvolatile semiconductor memory device including a charge trap layer having a higher density charge trap site than a conventional silicon nitride layer and having charge traps having a discrete energy level that may be stable to thermal excitation. Example embodiments also provide a method of manufacturing the nonvolatile semiconductor memory device.

A nonvolatile semiconductor memory device according to example embodiments may comprise a tunnel insulating layer on a semiconductor substrate, a charge trap layer on the tunnel insulating layer and including a dielectric layer doped with a transition metal, a blocking insulating layer on the charge trap layer, and a gate electrode on the blocking insulating layer.

The dielectric layer may be formed of one selected from the group consisting of SiₓO_{y}, HfₓO_{y}, ZrₓO_{y}, SiₓN_{y}, AlₓO_{y}, HfₓSi_{y}O_{Z}Nₖ, HfₓO_{y}N_{z}, and HfₓAl_{y}O_{z}. The transition metal may be a metal having a valence electron at a d-orbital.

The dielectric layer may be formed of HfₓO_{y} and the transition metal doped in the dielectric layer may be at least one transition metal selected from the group consisting of Ta, V, Ru, and Nb.

The dielectric layer may be formed of an AlₓO_{y} and the transition metal doped in the dielectric layer may be at least one transition metal selected from the group consisting of W, Ru, Mo, Ni, Nb, V, Ti, and Zn.

The transition metal may be doped to approximately 0.01 to 15 atomic %. The dielectric layer may be doped with at least two kinds of transition metals to simultaneously form electron traps and hole traps.

A method of manufacturing a nonvolatile semiconductor memory device according to example embodiments may comprise forming a first insulating layer as a tunnel insulating layer on a semiconductor substrate, forming a dielectric layer doped with a transition metal on the first insulating layer as a charge trap layer, forming a second insulating layer as a blocking insulating layer on the dielectric layer doped with a transition metal, forming a conductive layer for a gate electrode on the second insulating layer, and forming a gate stack by sequentially patterning the conductive layer, the second insulating layer, the dielectric layer doped with the transition metal, and the first insulating layer.

The dielectric layer may be formed of one selected from the group consisting of SiₓO_{y}, HfₓO_{y}, ZrₓO_{y}, SiₓN_{y}, AlₓO_{y}, HfₓSi_{y}O_{z}Nₖ, HfₓO_{y}N_{z}, and HfₓAl_{y}O_{z}.

The dielectric layer doped with the transition metal may be formed using a sputtering method, an atomic layer deposition (ALD) method, and/or a chemical vapor deposition (CVD) method.

The dielectric layer doped with the transition metal may be formed by forming a non-doped dielectric layer on the first insulating layer and then ion-implanting atoms of the transition metal into the non-doped dielectric layer.

The dielectric layer doped with the transition metal may be formed at about 800° or higher. The method may further comprise annealing the dielectric layer doped with the transition metal at about 800° or higher after forming the dielectric layer doped with the transition metal.

The annealing may be performed in an oxygen or a nitrogen atmosphere. In addition, the annealing may be performed using a rapid thermal annealing method or a furnace annealing method.

### BRIEF DESCRIPTION OF THE DRAWINGS

Example embodiments will be more clearly understood from the following detailed description taken in conjunction with the accompanying drawings. FIGS. 1-16 represent non-limiting, example embodiments as described herein.

FIG. 1 illustrates a cross-sectional view of a silicon-oxide-nitride-oxide-semiconductor (SONOS) device, which is an example of a conventional nonvolatile semiconductor memory device;

FIG. 2 illustrates a cross-sectional view of a nonvolatile semiconductor memory device according to example embodiments;

FIGS. 3A and 3B illustrate the energy level of a charge trap caused by vacancies of Hf and O in an HfO₂ layer;

FIGS. 4A through 4H illustrate the energy level of the charge trap when Ta, V, Ru, Nb, Mn, Pd, Ir, and Sb are substituted with Hf or O in the HfO₂ layer;

FIG. 5 is a graph illustrating the variation of formation energy according to doping conditions based on a variation of composition ratios of Hf and O of an HfₓO_{y} layer;

FIG. 6 illustrates transition metals in the periodic table that may be used in example embodiments;

FIGS. 7A and 7B illustrate the energy level of a charge trap caused by vacancies of Al and O in an Al₂O₃ layer;

FIGS. 8A through 8H illustrate the energy level of a charge trap when Zn, W, Mo, Ru, Si, Hf, Ni and PT are substituted with Al or O in an Al₂O₃ layer;

FIG. 9 is a graph illustrating the variation of formation energy according to doping conditions based on a variation of composition ratios of Al and O of an Al₂O₃ layer;

FIGS. 10A through 10C are cross-sectional views of prepared samples illustrating the advantages of example embodiments;

FIG. 11 illustrates a cross-sectional TEM image of Sample 3 illustrated in FIG. 10C;

FIGS. 12A through 12C are graphs illustrating the capacitance-voltage characteristics of the three samples illustrated in FIGS. 10A through 10C, respectively;

FIG. 13 is a graph illustrating the variation in the flat band voltage according to the programming/erasing time to exemplify the characteristics of a nonvolatile semiconductor memory device according to example embodiments;

FIG. 14 is a graph illustrating the variation in the flat band voltage as a function of time to exemplify the retention characteristics of a conventional nonvolatile semiconductor memory device;

FIG. 15 is a graph illustrating the variation in the flat band voltage as a function of time to exemplify the retention characteristics of a nonvolatile semiconductor memory device according to example embodiments; and

FIGS. 16A and 16B are cross-sectional views illustrating a method of manufacturing a nonvolatile semiconductor memory device according to example embodiments.

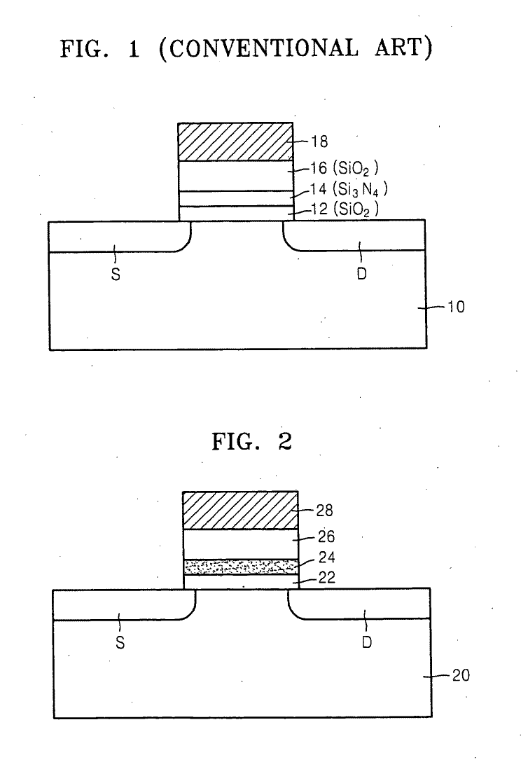

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A nonvolatile semiconductor memory device according to example embodiments may use a high-k dielectric layer having a dielectric constant of about 10 as a charge trap layer. A transition metal doped in the high-k dielectric layer may form a deeper charge trap stable to thermal excitation.

The deeper charge trap may have an energy level away from a valence band and a conduction band, and electrons or holes filled in the charge trap may not be easily excited by thermal excitation to the valence band or the conduction band. In contrast, a shallow charge trap may have an energy level below or above the conduction band, and electrons and holes filled in the shallow charge trap may be easily excited by thermal excitation and may contribute to electrical conduction.

As described above, a deeper charge trap that is stable to thermal excitation may be formed in the charge trap layer and the trapped charges may not be easily excited. As such, the retention characteristics of the nonvolatile memory device may be improved. Moreover, the energy level of the deeper charge trap may be controlled according to the type of doped transition metal, in which the distribution may be discrete and not broad. Thus, the charges trapped in the charge trap formed by an appropriate transition metal may be less likely to be thermally excited.

Because the deeper charge trap may be formed in a high-k dielectric layer which has a higher dielectric constant, the charge trap layer may have more charge traps at an equivalence of thickness (EOT) than a conventional silicon nitride layer. Also, the high-k dielectric layer may be better crystallized than a conventional amorphous silicon nitride layer. Thus, the charge trap formed in the high-k dielectric layer may have intrinsically higher stability. Accordingly, the retention characteristics of the nonvolatile semiconductor memory device according to example embodiments may be improved by increasing the density of the charge trap site of the charge trap layer and the thermal stability of the charge trap.

FIG. 2 is a cross-sectional view of a nonvolatile memory semiconductor device according to example embodiments.

Referring to FIG. 2, a tunnel insulating layer 22 may be formed on a semiconductor substrate 20. The tunneling insulating layer 22 may be a silicon oxide layer. A charge trap layer 24 formed of a dielectric layer doped with a transition metal may be formed on the tunnel insulating layer 22. A blocking insulating layer 26 may be formed on the charge trap layer 24 and a gate electrode 28 may be formed on the blocking insulating layer 26. The blocking insulating layer 26 may be a silicon oxide layer or an aluminum oxide layer, and the gate electrode 28 may be a doped polysilicon layer or a metal layer. Source and drain regions S and D may be formed in the substrate 20 on both sides of a gate stack in which the tunneling insulating layer 22, the charge trap layer 24, the blocking insulating layer 26, and the gate electrode 28 may be sequentially stacked. A surface of the semiconductor substrate 20 between the source and drain regions S and D (e.g., the surface of the semiconductor substrate 20 corresponding to the gate stack) may be a channel region.

The charge trap layer 24 may be a dielectric layer doped with a transition metal having a valence electron at a d-orbital. The dielectric layer may be a high-k dielectric layer selected from the group consisting of a HfₓO_{y} layer, a ZrₓO_{y} layer, an AlₓO_{y} layer, a HfₓSi_{y}O_{z}Nₖ layer, a Hf_{X}O_{Y}N_{Z} layer, and a HfₓAl_{y}O_{z} layer, and having a dielectric ratio of 10 or greater. The high-k dielectric layer may also be a SiₓO_{y} layer or a SiₓN_{y} layer.

The transition metal doped in the dielectric layer may be one type, two types, or more. When the doped transition metal is of two types or more, more electron traps and hole traps may be formed at the same time. The concentration of the doped transition metal may be approximately 0.01 to 15 atomic %.

When a metal transition metal (e.g., Ta, V, Ru, Nb, Mn, Pd, Ir, or Sb) is doped in a HfO₂ layer having no defects and a complete structure, the number of the outermost electrons of the transition metal may be different from that of Hf. Thus, surplus electrons or holes may be created which do not participate in bonding. These surplus electrons and holes may function as a hole trap or electron trap.

When a transition metal is doped in a HfₓO_{y} layer, the doped transition metal atom may be substituted with a hafnium (Hf) atom or an oxygen (O) atom, or inserted into a unit cell of HfₓO_{y} or into a vacancy of an original atom. The stable energy level of the charge trap formed may be decided by quantum mechanic calculation. Therefore, the energy level of the charge trap may vary according to the kind of doped transition metal:

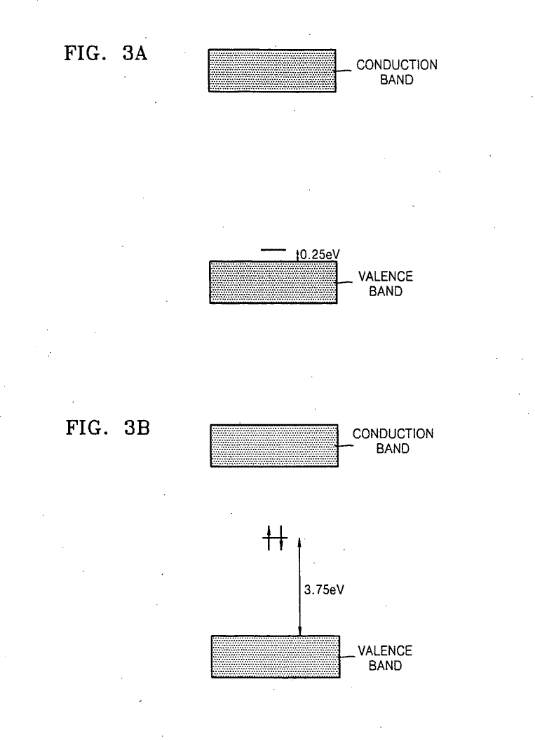

FIGS. 3A and 3B illustrate the energy level of the charge trap generated when there may be vacancies of Hf and O in the HfO₂ layer.

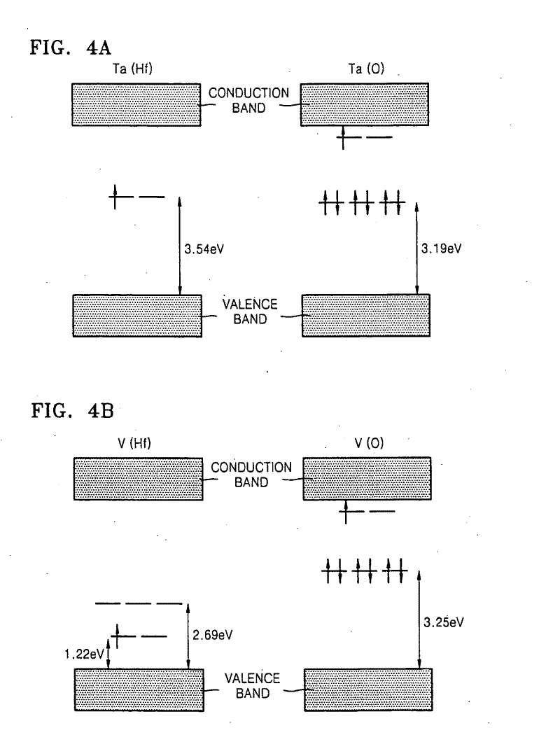

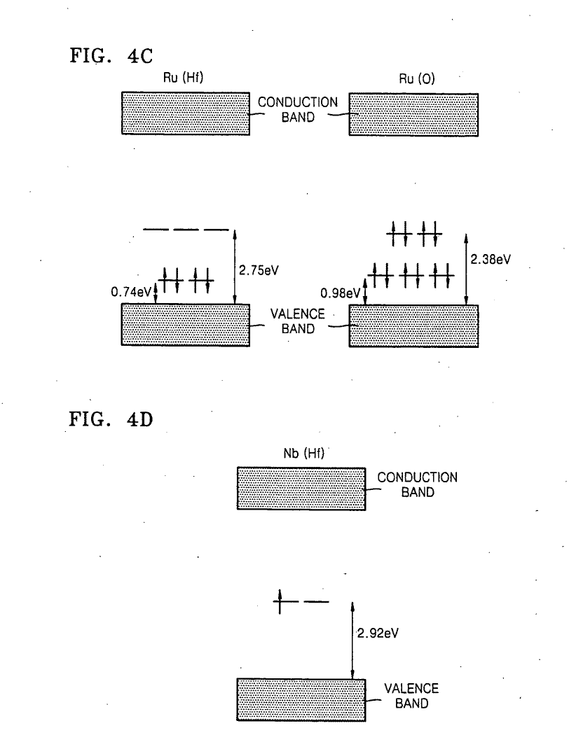

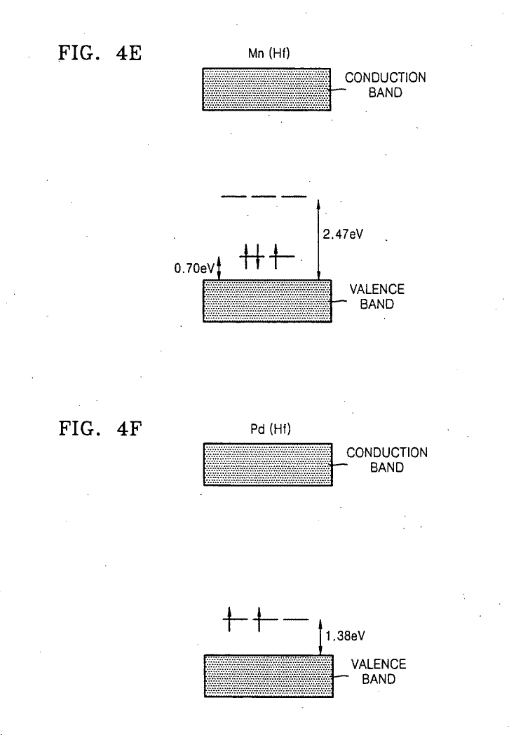

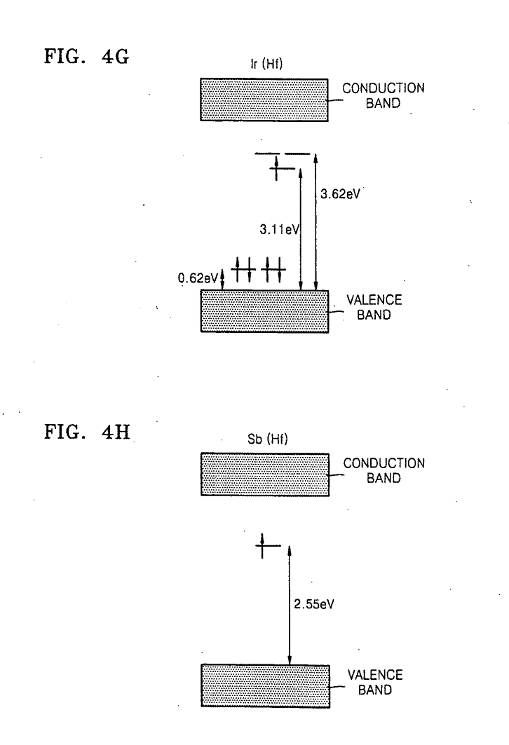

FIGS. 4A through 4H illustrate the energy level of the charge trap that may be generated when Ta, V, Ru, Nb, Mn, Pd, Ir, or Sb doped in the HfO₂ layer is substituted with Hf or O. The arrow illustrating the charge trap energy level indicates that surplus electrons may be filled. When such surplus electrons are separated away, holes may be trapped. On the other hand, a vacant charge trap energy level indicates the presence of holes, in which electrons may be trapped. Also, ‘A(B)’ means that A is substituted in the place of B.

Referring to FIG. 4A, when Ta is substituted with Hf, three electrons and a hole may be trapped per Ta atom. When Ta is substituted with O, the doping effect of n type impurities may be shown in the HfO₂ layer and charge traps may be generated, which may catch a plurality of holes. When Ta is substituted with O, only hole traps may function as a deeper charge trap.

Referring to FIG. 4B, when V is substituted with Hf, nine electrons and a hole may be trapped per V atom. Also, when V is substituted with O, the doping effect of n type impurities may be shown in the HfO₂ layer and charge traps may be generated, which may catch a plurality of holes.

Referring to FIG. 4C, when Ru is substituted with Hf, six electrons and four holes may be trapped per Ru atom. The electron traps that may catch six electrons may function as a deeper charge trap. When Ru is substituted with O, ten holes may be trapped per Ru atom.

Referring to FIG. 4D, when Nb is substituted with Hf, three electrons and one hole may be trapped per Nb atom.

Referring to FIG. 4E, when Mn is substituted with Hf, seven electrons and three holes may be trapped per Mn atom. The electron traps that may catch six electrons may function as a deeper charge trap.

Referring to 4F, when Pd is substituted with Hf, four electrons and two holes may be trapped per Pd atom.

Referring to FIG. 4G, when Ir is substituted with Hf, five electrons and five holes may be trapped per Ir atom. The hole traps that may be adjacent to the valence band may not function as a deeper charge trap.

Referring to 4H, when Sb is substituted with Hf, one electron and one hole may be trapped per Sb atom.

According to FIGS. 4A through 4H, Ta, V, Ru, and Nb may form a deeper charge trap in the HfO₂ layer and more charge trap sites. Thus, when the high-k dielectric layer used as the charge trap layer 24 is a HfO₂ layer, the transition metal to be doped may be Ta, V, Ru, or Nb. Using the simulation results in calculating the energy level of the charge trap formed by the doped transition metal, a dielectric layer and a suitable transition metal may be obtained.

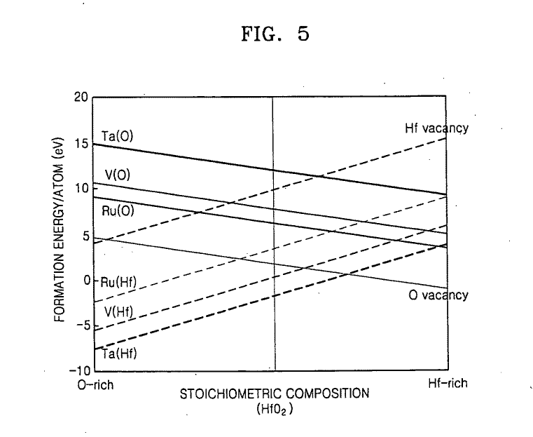

FIG. 5 is a graph illustrating the variation in formation energy per atom according to the composition ratios of Hf and O of the HfₓO_{y} layer. ‘A(B)’ refers to energy required to substitute A with B, and ‘A vacancy’ refers to energy required to create a vacancy of A.

Referring to FIG. 5, because Ta(0), V(O), and Ru(O) are greater than Ta(Hf), V(Hf), and Ru(Hf), respectively, Ta, V, and Ru atoms may likely be substituted with Hf, and not O, when a HfO₂ layer having a stoichiometric composition is used. The formation energy may vary according to the composition variation of Hf and O and a graph illustrating the result may be used in selecting the doping conditions of the transition metal.

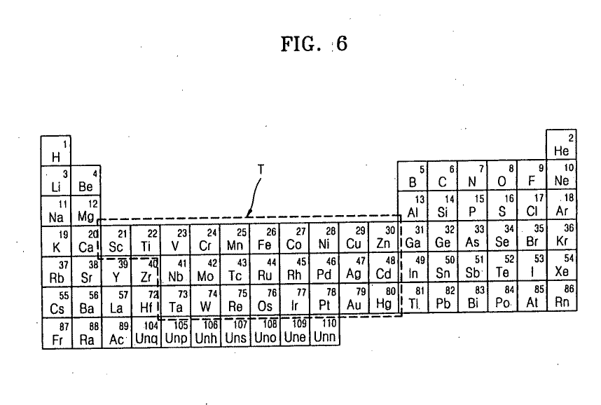

FIG. 6 is a view of the periodic table displaying transition metals that may be used in example embodiments. Inside of the dotted lines illustrates region T. Based on FIGS. 4A through 4H, the atoms on the right side of region T may have increasingly more electron traps, and the atoms below region T may have higher charge trap energy levels.

The doping of a transition metal in a high-k dielectric and amorphous AlₓO_{y} layer may be simulated whereby the transition metal doped in the AlₓO_{y} layer is substituted with an aluminum atom or an oxygen atom, or inserted into a unit cell of AlₓO_{y} or into a vacancy of an original atom. The more stable deeper energy level formed may be decided by a quantum mechanic calculation.

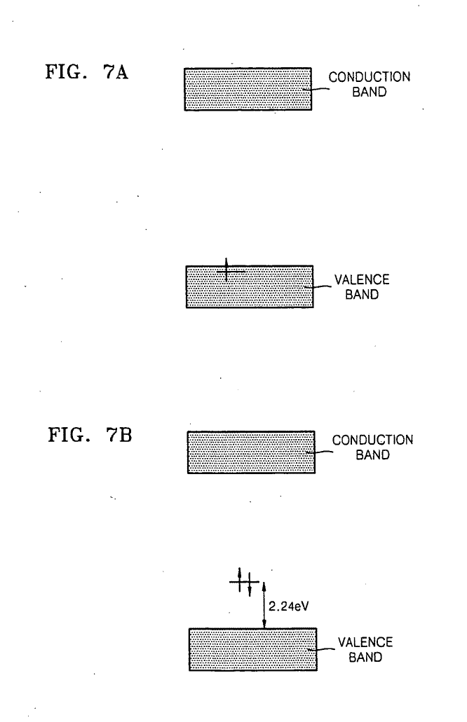

FIGS. 7A and 7B illustrate the energy level of charge traps generated when vacancies of Al and O may be generated in the Al₂O₃ layer.

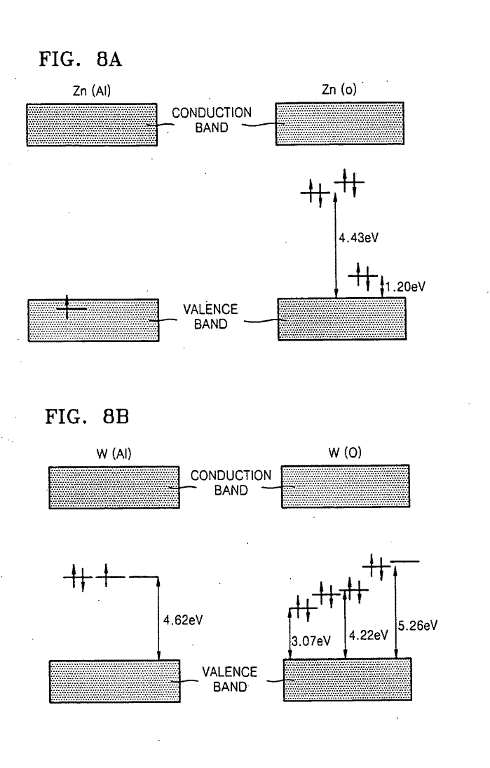

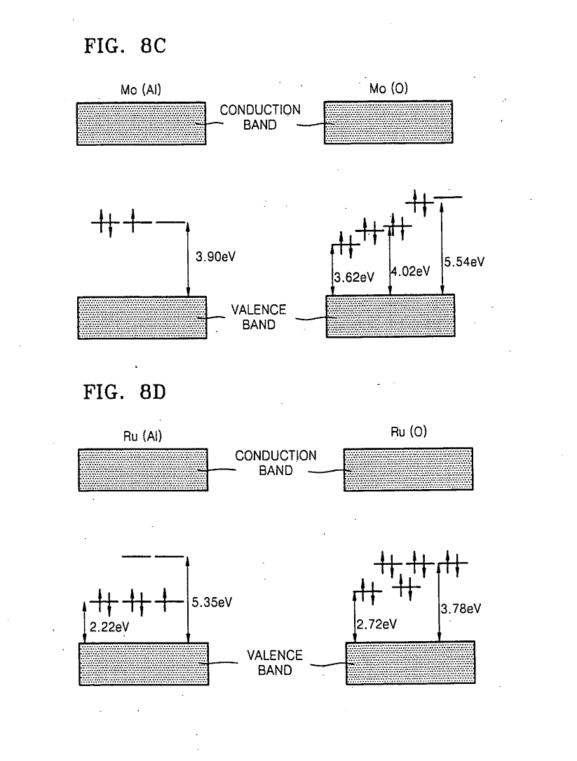

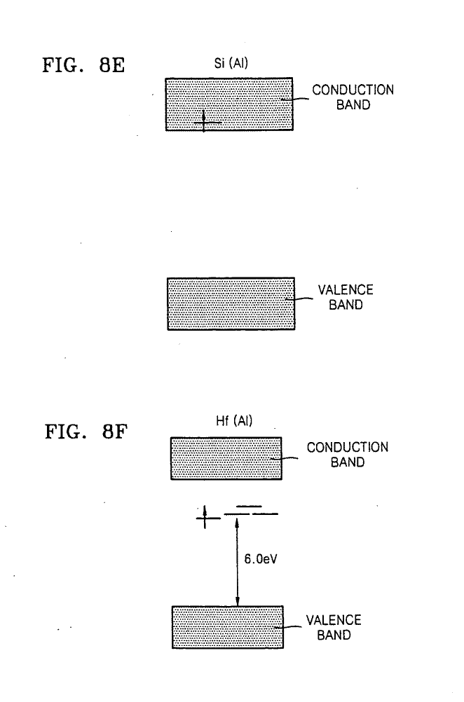

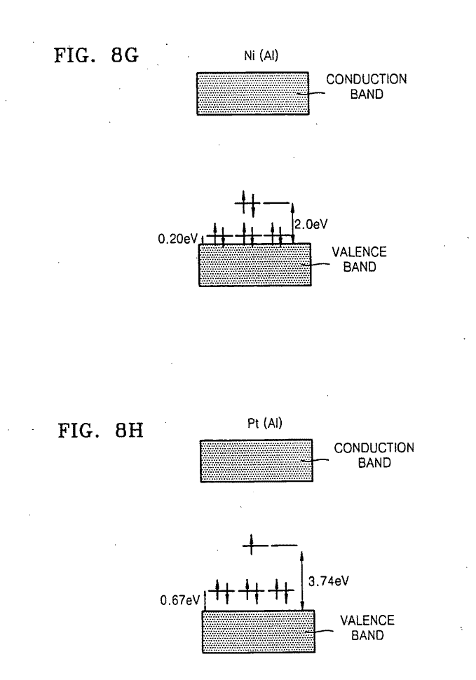

FIGS. 8A through 8H illustrate the energy level of the charge trap that may be generated when Zn, W, Mo, Ru, Si, Hf, Ni, and Pt are substituted with Hf or O in the Al₂O₃ layer. The arrow illustrating the charge trap energy level indicates that surplus electrons may be filled. When such surplus electrons are separated away, holes may be trapped. On the other hand, a vacant charge trap energy level indicates the presence of holes, in which electrons may be trapped. In addition, ‘A(B)’ means that A is substituted in the place of B.

Referring to FIG. 8A, when Zn is substituted with Al, no charge trap may be generated, and only the doping effect of p type impurities may be shown. When Zn is substituted with O, charge traps may be generated, which may catch a plurality of holes.

Referring to FIG. 8B, when W is substituted with Al, three electrons and three holes may be trapped per W atom. When W is substituted with O, eight holes and two electrons may be trapped.

Referring to FIG. 8C, when Mo is substituted with Al, three electrons and three holes may be trapped per Mo atom. When Mo is substituted with O, eight holes and two electrons may be trapped.

Referring to FIG. 8D, when Ru is substituted with Al, five electrons and five holes may be trapped per Ru atom. When Ru is substituted with O, ten holes may be trapped.

Referring to FIG. 8E, when Si is substituted with Al, no charge trap may be generated, and the doping effect of n type impurities may be shown.

Referring to FIG. 8F, when Hf is substituted with Al, both electron and hole traps may be generated, and these charge traps may be more shallow charge traps.

Referring to FIG. 8G, when Ni is substituted with AI, a plurality of electron and hole traps may be generated. However, portions of the electron and hole traps may be adjacent to the valence band.

Referring to FIG. 8H, when Pt is substituted with Al, a plurality of electron and hole traps may be generated.

According to the results shown in FIGS. 8A through 8H, W, Ru, Mo, Ni, Nb, V, Ti, and Zn may form deeper charge traps in the Al₂O₃ layer and may form more charge trap sites. Thus, when the high-k dielectric layer used as the charge trap layer 24 is an Al₂O₃ layer, the transition metal to be doped may be W, Ru, Mo, Ni, or Zn. Also, Nb, V, or Ti may be used as a transition metal doped in the Al₂O₃ layer. Using the simulation results calculating the energy level of the charge trap formed by the doped transition metal, a dielectric layer and a suitable transition metal may be obtained.

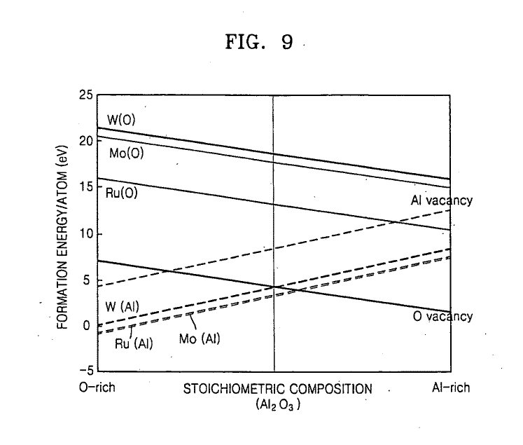

FIG. 9 is a graph illustrating the variation in formation energy per atom according to the composition ratios of Al and O of the AlₓO_{y} layer. ‘A(B)’ refers to energy required to substitute A with B, and ‘A vacancy’ refers to energy required to create a vacancy of A.

Referring to FIG. 9, because W(O), Ru(O), and Mo(O) may be greater than W(AI), Ru(AI), and Mo(AI), respectively, W, Ru, and Mo atoms may likely be substituted with AI, and not O, when an Al₂O₃ layer having a stoichiometric composition is used. The formation energy may vary according to the composition variation of Al and O, and a graph illustrating the result may be used in selecting the doping conditions of the transition metal.

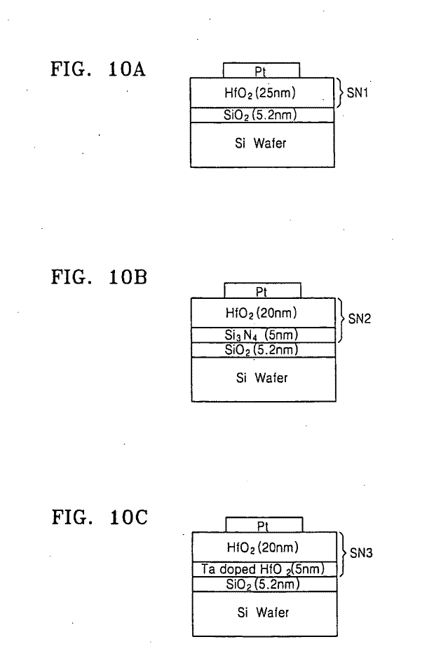

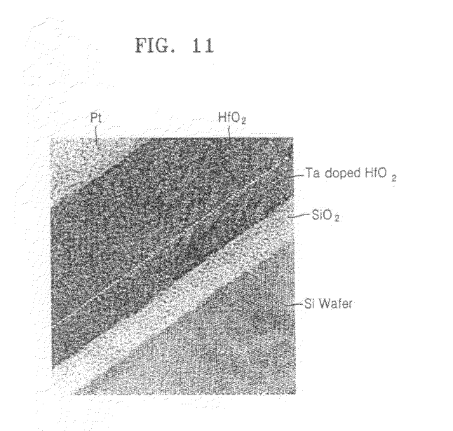

FIGS. 10A through 10C are cross-sectional views of prepared samples for illustrating the advantages of example embodiments. Using metal-oxide-semiconductor (MOS) transistors may enable more precise examination. However, for ease of experimentation, samples having simple structures as illustrated in FIGS. 10A through 10C were prepared. All three samples are stacks in which a Si wafer, a silicon oxide (SiO₂) layer, a storage node (SN1, SN2, SN3), and a Pt electrode may be sequentially stacked. The storage node SN1 of Sample 1 in FIG. 10A may be a non-doped single HfO₂ layer. The storage node SN2 of Sample 2 in FIG. 10B may be a stacked layer of a non-doped Si₃N₄ layer and a non-doped HfO₂ layer. The storage node SN3 of Sample 3 in FIG. 10C may be a stacked layer of a HfO₂ layer doped with Ta and a non-doped HfO₂ layer. FIG. 11 is a cross-sectional TEM image of Sample 3.

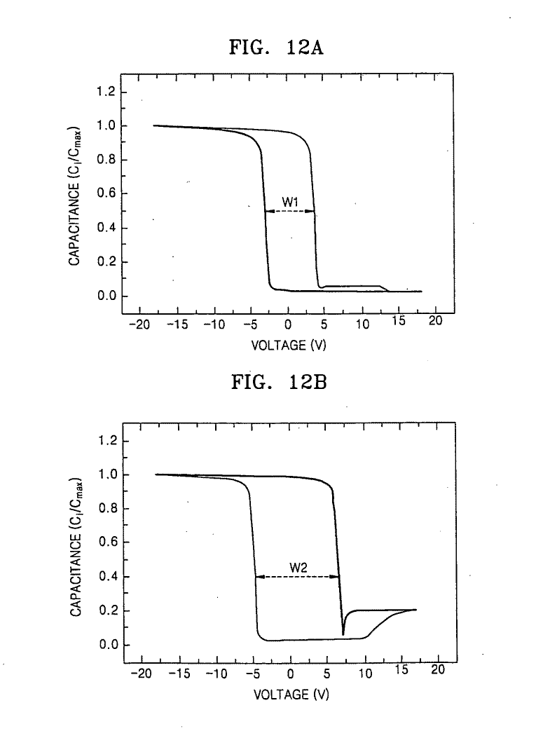

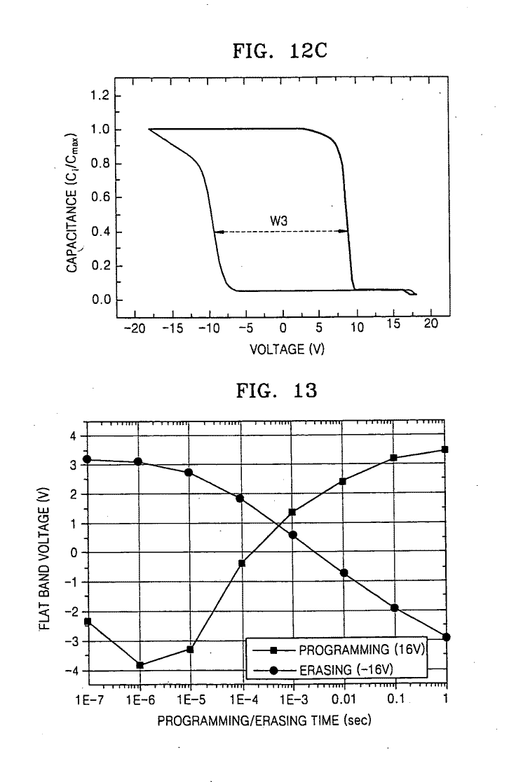

FIGS. 12A through 12C are graphs illustrating the capacitance-voltage characteristics of Samples 1-3, respectively.

Referring to FIGS. 12A through 12C, the width of a central portion of Sample 3 may be the broadest among the widths of the central portion of a capacitance-voltage hysteresis curve of Samples 1-3. This may indicate that the number of charge traps formed in the storage node SN3 of Sample 3 may be the greatest, which may be due to the HfO₂ layer doped with Ta.

As described above, the width of the central portion of the capacitance-voltage hysteresis curve of a charge trap layer used in the nonvolatile semiconductor memory device according to example embodiments may be increased. This may indicate that the memory window is increased. Thus, using example embodiments, a nonvolatile semiconductor memory device which is multi-bit programmable may be manufactured.

FIG. 13 is a graph illustrating the operating speed of Sample 3.

Referring to FIG. 13, the speed of the flat band voltage (V) may vary according to the maintenance time (sec) of a pulse current during programming and/or erasing. The erasing speed may be slower than the programming speed. Thus, the varying speed of the flat band voltage may be slower when erasing than programming. This may prove that a plurality of deeper charge traps may be formed in the HfO₂ layer doped with Ta.

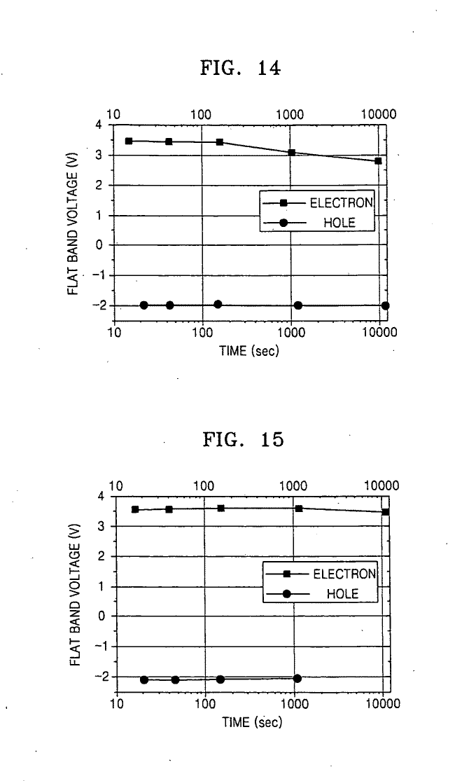

FIG. 14 is a graph illustrating the retention characteristics of a conventional nonvolatile semiconductor memory device having a charge trap layer (a silicon nitride layer). FIG. 15 is a graph illustrating the retention characteristics of Sample 3 according to example embodiments.

In the conventional charge trap layer of FIG. 14, the flat band voltage (V) may vary over time because current leaks over time, but in the charge trap layer according to example embodiments, the flat band voltage (V) may hardly change within the measurement range over time. Thus, example embodiments, which use deeper charge traps, may have a longer retention time than that of the conventional art.

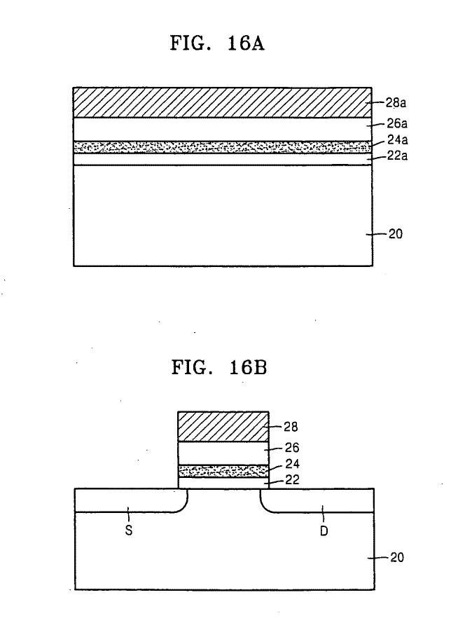

FIGS. 16A and 16B are cross-sectional views illustrating a method of manufacturing a nonvolatile semiconductor memory device according to example embodiments.

Referring to FIG. 16A, a first insulating layer 22a may be formed on a semiconductor substrate 20 as a tunnel insulating layer, and a dielectric layer 24a doped with a transition metal may be formed as a charge trap layer on the first insulating layer 22a. The dielectric layer 24a may be a high-k dielectric layer formed of a material selected from the group consisting of HfₓO_{y}, ZrₓO_{y}, AlₓO_{y}, HfₓSi_{y}O_{z}Nₖ, HfₓO_{y}N_{z}, and HfₓAl_{y}O_{z}, or of a SiₓO_{y} layer or a SiₓN_{y} layer.

The dielectric layer 24a doped with the transition metal may be formed using one of four methods described below.

A first method may include a dielectric layer 24a doped with the transition metal being formed using a sputtering method. A single target doped with a transition metal and having a controlled composition ratio may be used, or two individual targets may be used.

A second method may include the dielectric layer 24a doped with the transition metal being formed using an atomic layer deposition (ALD) method.

A third method may include the dielectric layer 24a doped with the transition metal being formed using a chemical vapor deposition (CVD) method. A mixed source including a precursor of the transition metal and having a controlled composition ratio may be used, or two or more individual sources may be used.

A fourth method may include the dielectric layer 24a doped with the transition metal being formed by forming a non-doped dielectric layer on the first insulating layer 22a and then ion-implanting the transition atom in the non-doped dielectric layer.

The doping concentration of the transition metal in the four methods may be controlled. The doping concentration of the transition metal may be approximately 0.01 to 15 atomic %.

The dielectric layer 24a doped with the transition metal may be formed at 800° or higher. Thus, the crystalline structure of the dielectric layer may be stabilized and the doped transition metal atom may be substituted to a more stable location.

If the stability of the crystalline structure when forming the dielectric layer 24a doped with the transition metal is insufficient, the dielectric layer 24a doped with the transition metal may be post-annealed at 800° or higher after forming the dielectric layer 24a doped with the transition metal. The post-annealing may be performed for several minutes to several dozens of minutes in an oxygen or a nitrogen atmosphere, either using a rapid thermal annealing (RTA) method and/or a furnace annealing method.

After forming the dielectric layer 24a doped with the transition metal, a second insulating layer 26a may be formed as a blocking insulating layer on the dielectric layer 24a doped with the transition metal. A conductive layer 28a as a gate electrode may be formed on the second insulating layer 26a.

Referring to FIG. 16B, the conductive layer 28a, the second insulating layer 26a, the dielectric layer doped with the transition metal 24a, and the first insulating layer 22a may be patterned as a gate to form a gate stack in which a tunnel insulating layer 22, a charge trap layer 24, a blocking insulating layer 26, and a gate electrode 28 may be sequentially stacked.

Impurities may be ion-implanted in the semiconductor substrate 20 on both sides of the gate stack to form source and drain regions S and D.

Though not illustrated in the drawings, known post-processes may be performed in order to manufacture a nonvolatile semiconductor memory device according to example embodiments.

As described above, a dielectric layer (e.g., a high-k dielectric layer) in which a deeper charge trap may be formed by doping a transition metal may be used as a charge trap layer in example embodiments. As such, the thermal stability of the charge trap formed in the charge trap layer may be increased in comparison to the conventional art, and the charge trap density may also be higher than that of the conventional art. Accordingly, the retention characteristics of the nonvolatile semiconductor memory device of example embodiments may be improved. Moreover, because the memory window of the nonvolatile semiconductor device may be broadened, the nonvolatile semiconductor device of example embodiments may be used as a multi-bit programming device.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A method of manufacturing a nonvolatile semiconductor memory device, the method comprising:
forming a first insulating layer as a tunnel insulating layer on a semiconductor substrate;
forming a dielectric layer doped with a transition metal on the first insulating layer as a charge trap layer;
forming a second insulating layer as a blocking insulating layer on the dielectric layer doped with a transition metal;
forming a conductive layer for a gate electrode on the second insulating layer; and
forming a gate stack by sequentially patterning the conductive layer, the second insulating layer, the dielectric layer doped with the transition metal, and the first insulating layer.

2. The method of claim 1, wherein the dielectric layer is formed of one selected from the group consisting of SiₓO_{y}, HfₓO_{y}, ZrₓO_{y}, SiₓN_{y}, AlₓO_{y}, Hf_{X}Si_{y}O_{Z}Nₖ, HfₓO_{y}N_{z}, and HfₓAl_{y}O_{z}.

3. The method of claim 1, wherein the dielectric layer doped with the transition metal is formed using a sputtering method.

4. The method of claim 1, wherein the dielectric layer doped with the transition metal is formed using an atomic layer deposition (ALD) method.

5. The method of claim 1, wherein the dielectric layer doped with the transition metal is formed using a chemical vapor deposition (CVD) method.

6. The method of claim 1, wherein the dielectric layer doped with the transition metal is formed by forming a non-doped dielectric layer on the first insulating layer and then ion-implanting atoms of the transition metal into the non-doped dielectric layer.

7. The method of claim 1, wherein the dielectric layer doped with the transition metal is formed at 800° or higher.

8. The method of claim 1, further comprising annealing the dielectric layer doped with the transition metal at 800° or higher after forming the dielectric layer doped with the transition metal.

9. The method of claim 8, wherein the annealing is performed in an oxygen or a nitrogen atmosphere.

10. The method of claim 8, wherein the annealing is performed using a rapid thermal annealing method or a furnace annealing method.
